(19) United States
(12) Patent Application Publication
(10) Pub. No.: US 2011/0298018 A1
(43) Pub. Date: Dec. 8, 2011

(54) TRANSISTOR AND MANUFACTURING METHOD OF THE SAME

(75) Inventors: Haizhou Yin, Poughkeepsie, NY (US); Zhijiong Luo, Poughkeepsie, NY (US); Huilong Zhu, Poughkeepsie, NY (US)

(73) Assignee: Institute of Microelectronics, Chinese Academy of Sciences, Beijing (CN)

(21) Appl. No.: 12/937,502

(22) PCT Filed: Jun. 28, 2010
(86) PCT No.: PCT/CN2010/074607

§ 371 Date: Oct. 12, 2010

(30) Foreign Application Priority Data
Dec. 31, 2009 (CN) 200910249095

(51) Int. Cl. H01L 29/78; H01L 21/336

(52) U.S. Cl. 257/288; 438/286; 257/E29.255; 257/E21.409

(57) ABSTRACT

The invention provides a transistor, including: a substrate having a channel region; a source region and a drain region on two ends of the channel region of the substrate respectively; a gate high-K dielectric layer on a top surface of the substrate above the channel region between the source region and the drain region; an interfacial layer under the gate high-K dielectric layer, including a first portion near the source region and a second portion near the drain region, wherein an equivalent oxide thickness of the first portion is larger than that of the second portion. An asymmetric replacement metal gate forms an asymmetric interfacial layer, which is thin at the drain region side and thick at the source region side. At the thin drain region side, the short channel effect is significant and the asymmetric interfacial layer advantageously suppresses the short channel effect. At the thick source region side, the carrier mobility has a large influence on the device, and the asymmetric interfacial layer prevents the carrier mobility from decreasing. Further, the asymmetric replacement metal gate implements an asymmetric metal work function.

### FIELD OF THE INVENTION

The invention relates to a transistor, in particular, a transistor having a gate of asymmetric structure and a manufacturing method of the same.

### BACKGROUND OF THE INVENTION

A main factor that prevents further reducing the size of the metal oxide semiconductor (MOS) transistor is the short channel effect (SCE), which occurs mainly when the length of the channel is less than 0.1 μm. Device malfunction includes but is not limited to: DIBL (drain-induced barrier lowering, corresponding to a low source-drain breakdown voltage); sub-threshold leakage; and threshold instability, etc. These problems are generally called short channel effect, which mainly relates to the equivalent oxide thickness (EOT) of the interfacial layer. A thin EOT advantageously suppresses SCE especially at the drain, cf. High-Performance High-K/Metal Gates for 45 nm CMOS and Beyond with Gate-First Processing (M. Chudzik et al. VLSI 2007, IBM et al.). As shown in FIG. 1, when the electrical thickness Tiny (the equivalent oxide thickness EOT) of the gate oxide layer reduces, the DIBL reduces accordingly.

Further, as disclosed in Extremely Scaled Gate-First High-i K Metal Gate Stack with EOT of 0.55 nm Using Novel Interfacial Layer Scavenging Techniques for 22 nm Technology Node and Beyond (K. Choi et al. VLSI 2009, IBM), when the equivalent oxide thickness (EOT) continues to reduce, the electron mobility (at E_{eff}=1 MV/cm) continues to decrease, as shown in FIG. 2. Meanwhile, when the equivalent oxide thickness (EOT) continues to reduce, the cavity mobility (at E_{eff}=1 MV/cm) also continues to decrease, as shown in FIG. 3. This shows that the interfacial layer will cause the decrease of the carrier mobility.

Therefore, it is desired to provide a transistor and the manufacturing method thereof, in order to control the decrease of the carrier mobility while lowering down the equivalent oxide thickness (EOT) to suppress the short channel effect.

### SUMMARY OF THE INVENTION

In an embodiment of the present invention, a transistor includes: a substrate having a channel region; a source region and a drain region on two ends of the channel region of the substrate respectively; a gate high-K dielectric layer on a top surface of the substrate above the channel region between the source region and the drain region; an interfacial layer under the gate high-K dielectric layer, including a first portion near the source region and a second portion near the drain region, wherein an equivalent oxide thickness of the first portion is larger than that of the second portion.

According to an embodiment of the transistor, the equivalent oxide thickness of the first portion of the interfacial layer is larger than 0.5 nm, and the equivalent oxide thickness of the second portion of the interfacial layer is smaller than 0.5 nm.

According to an embodiment of the transistor, the length of the first portion of the interfacial layer is less than ⅔ of the total length of the interfacial layer, and the second portion has a length equal to the remaining portion of the total length.

According to an embodiment of the transistor, the transistor further includes: an oxygen absorbing layer on the top surface of the gate high-K dielectric layer; and a masking layer surrounding the oxygen absorbing layer.

According to an embodiment of the transistor, the oxygen absorbing layer includes: a first oxygen absorbing layer at the drain region side and in contact with the gate high-K dielectric layer; and a second oxygen absorbing layer at the source region side and in contact with the gate high-K dielectric layer, wherein the first oxygen absorbing layer has a better oxygen absorbing ability than that of the second oxygen absorbing layer.

According to an embodiment of the transistor, the first oxygen absorbing layer is formed from Ti, Hf, Ta, W, and/or nitride thereof.

According to an embodiment of the transistor, the dielectric constant of the gate high-K dielectric layer is larger than 4.

According to an embodiment of the transistor, the gate high-K dielectric layer is formed from HfO₂, ZrO₂, or Al₂O₃.

According to an embodiment of the transistor, a metal film is formed above the gate high-K dielectric layer.

According to an embodiment of the transistor, the metal film is formed from Ti, Ta, Al, or nitride thereof.

An asymmetrical replacement metal gate forms an asymmetric interfacial layer, which is thin at the drain region side and thick at the source region side. At the thin drain region side, the short channel effect is significant and the asymmetric interfacial layer facilitates suppressing the short channel effect. At the thick source region side, the carrier mobility has a large influence on the device, and the asymmetric interfacial layer prevents the carrier mobility from decreasing.

Further, the asymmetric replacement metal gate can provide an asymmetric metal work function.

The present invention further provides a manufacturing method of a transistor, including: manufacturing a source, a drain, a gate high-K dielectric layer, a sacrificial gate (generally a polysilicon gate), and a masking layer covering the sacrificial gate on a silicon wafer; depositing an interlayer dielectric on the masking layer, the source, and the drain; planarizing to remove the top of the interlayer dielectric to expose the top of the masking layer; etching to remove the top of the masking layer to expose the top of the sacrificial gate; etching to remove the sacrificial gate on the gate high-K dielectric layer to form a cavity; forming a first oxygen absorbing layer in the cavity; and forming a second oxygen absorbing layer in the remaining portion of the cavity, wherein the first oxygen absorbing layer has a better oxygen absorbing ability than that of the second oxygen absorbing layer.

In an alternative embodiment of the method, after etching to remove the sacrificial gate, a metal film is formed on the gate high-K dielectric layer.

In an alternative embodiment of the method, the metal film is formed from Ti, Ta, Al, and/or nitride thereof.

In an alternative embodiment of the method, the gate high-K dielectric layer is formed from high-K dielectric material having a dielectric constant larger than 4.

In an alternative embodiment of the method, the masking layer is formed from silicon oxide, silicon nitride, or a compound thereof.

In an alternative embodiment of the method, the interlayer dielectric is formed from silicon dioxide.

In an alternative embodiment of the method, the masking layer is removed by chemical mechanical planarization or reactive ion etching.

In an alternative embodiment of the method, a first oxygen absorbing material is slantingly deposited on the interlayer dielectric, the masking layer, and the gate high-K dielectric layer at the drain side of the cavity at one time.

In an alternative embodiment of the method, the first oxygen absorbing layer is formed from Ti, Hf, Ta, W, and/or nitride thereof.

In an alternative embodiment of the method, a second oxygen absorbing material is deposited in the remaining portion of the cavity and is polished by chemical mechanical planarization to form the second oxygen absorbing layer on the gate high-K dielectric layer at the source side of the cavity. The second oxygen absorbing material can be the same as the first oxygen absorbing material.

The above technical solution of the present invention can be better understood in conjunction with the following description and accompany drawings. However, it should be noted that the following description is about the preferable embodiments of the present invention and various relative details. The embodiments of the present invention are illustrated by examples. Further changes and modifications can be made within the scope of the present invention without departing from the spirit of the present invention. Such changes and modifications are all covered by the present invention.

### BRIEF DESCRIPTION OF THE DRAWINGS

FIG. 1 shows a comparison between the DIBL and L_{gate} at different Tᵢₙᵥ points;

FIG. 2 shows a variation trend of the electron mobility (at E_{eff}=1 MV/cm) with respect to EOT;

FIG. 3 shows a variation trend of the cavity mobility (at E_{eff}=1 MV/cm) with respect to EOT;

FIG. 4 shows a schematic view of the cross section of a transistor according to an embodiment of the present invention;

FIG. 5 shows a schematic view of the cross section in step 1 of the method for manufacturing the transistor according to an embodiment of the present invention;

FIG. 6 shows a schematic view of the cross section in step 2 of the method for manufacturing the transistor according to an embodiment of the present invention;

FIG. 7 shows a schematic view of the cross section in step 3 of the method for manufacturing the transistor according to an embodiment of the present invention;

FIG. 8 shows a schematic view of the cross section in step 4 of the method for manufacturing the transistor according to an embodiment of the present invention;

FIG. 9 shows a schematic view of the cross section in step 5 of the method for manufacturing the transistor according to an embodiment of the present invention;

FIG. 10 shows a schematic view of the cross section in step 6 of the method for manufacturing the transistor according to an embodiment of the present invention;

FIG. 11 shows a schematic view of the cross section in step 6 of the method for manufacturing the transistor according to an embodiment of the present invention;

and

FIG. 12 shows a schematic view of the cross section in step 7 of the method for manufacturing the transistor according to an embodiment of the present invention.

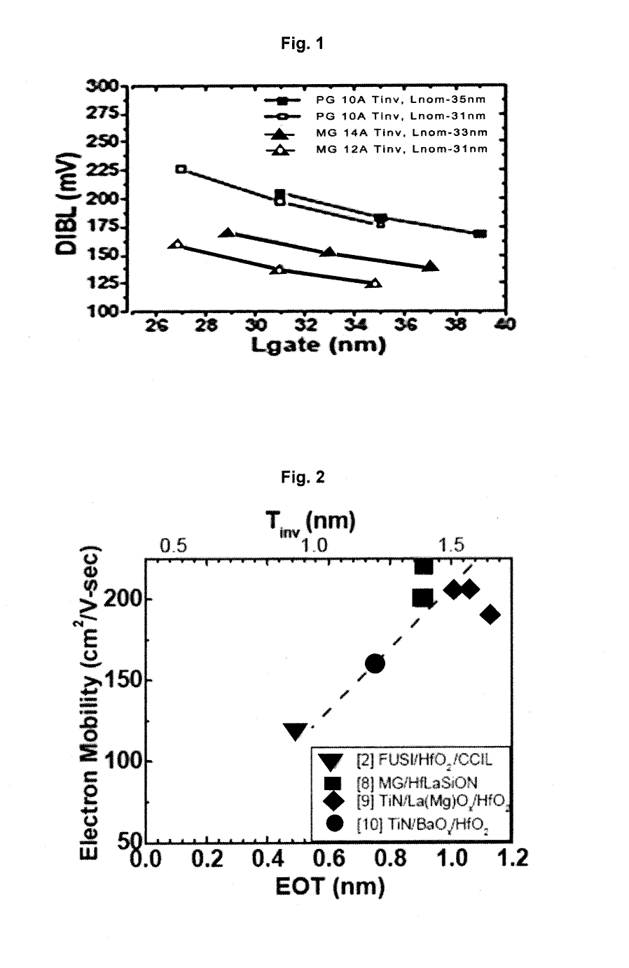

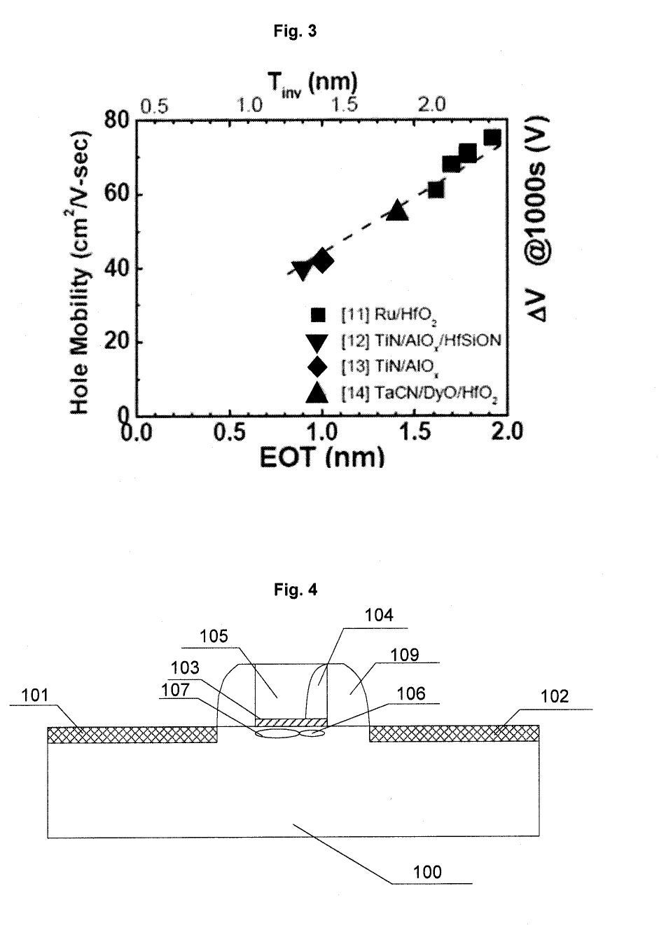

### DETAILED DESCRIPTION OF PREFERRED EMBODIMENTS

Various features and advantages of the present invention will be described with reference to embodiments and the accompany drawings. It should be noted that the features in the accompany drawings are not drawn to scale. Description of well-known components and processing techniques is omitted to clarify the present invention. The embodiments described herein are only for facilitating understanding and implementing the present invention by those skilled in the art. Therefore, the scope of the present invention is not limited to the embodiments.

As described above, the present invention relates to a transistor, in particular, a transistor having an asymmetric replacement gate, relative characteristics of which will be described in details herein. It should be noted that similar or corresponding parts will be denoted by identical reference signs.

As shown in FIG. 4, the structure of a transistor according to an embodiment of the present invention includes: a substrate 100 having a channel region; a source region 101; a drain region 102; a gate high-K dielectric layer 103 formed on a top surface of the substrate 100 by conventional process, the dielectric constant of which is larger than 4; an oxygen absorbing layer on a top surface of the gate high-K dielectric layer 103, including a first oxygen absorbing layer 104 on the gate high-K dielectric layer 103 at the drain side and a second oxygen absorbing layer 105 on the gate high-K dielectric layer 103 at the source side; and a masking layer 109 surrounding the oxygen absorbing layer.

The first oxygen absorbing layer 104 and the second oxygen absorbing layer 105 can absorb oxygen, and consequently reduce the equivalent oxide thickness (EOT) of an underlying interfacial layer by absorbing oxygen. The ability of absorbing oxygen of the first oxygen absorbing layer 104 is stronger than that of the second oxygen absorbing layer 105. Therefore, the interfacial layer thus formed includes a portion 106 and a portion 107 having different equivalent oxide thicknesses (EOT). The thickness of the portion 107 of the interfacial layer is larger than that of the portion 106. As a result, the portion 106 of the interfacial layer advantageously suppresses the short channel effect at the drain side, and the portion 107 of the interfacial layer advantageously prevents decrease of the carrier mobility at the source side. Meanwhile, the asymmetric gate can implement different effective work functions by using different materials.

Regarding the thickness of the interfacial layer, the thickness of the portion 106 of the interfacial layer is less than 0.5 nm and preferably less than 0.3 nm. The thickness of the portion 107 of the interfacial layer is larger than 0.5 nm. Regarding the length of the interfacial layer, the portion 106 of the interfacial layer is at a side of the interfacial layer near the drain and takes a length of no less than ⅓ of the total length thereof. The portion 107 of the interfacial layer takes the remaining length.

Materials for forming the layers may include but are not limited to the following examples. The gate high-K dielectric layer 103 may be formed from HfO₂, ZrO₂, and Al₂O₃, etc. The first oxygen absorbing layer 104 may be formed from pure metal Ti, Hf, Ta, W, and/or nitride thereof (cf. US Patent Application Publication No. 2009/0152651).

Alternatively, a metal film 103′ is formed on the gate high-K dielectric layer 103 before the formation of the oxygen absorbing layer, in order to adjust the threshold voltage V_{T} of the transistor. The metal film 103′ can be formed from pure Ti, Ta, Al, and/or nitride thereof, such as AlN, and TaAlN, etc.

As described above, the present invention also relates to a method for manufacturing a transistor, in particular, to a method for manufacturing a transistor having an asymmetric replacement gate.

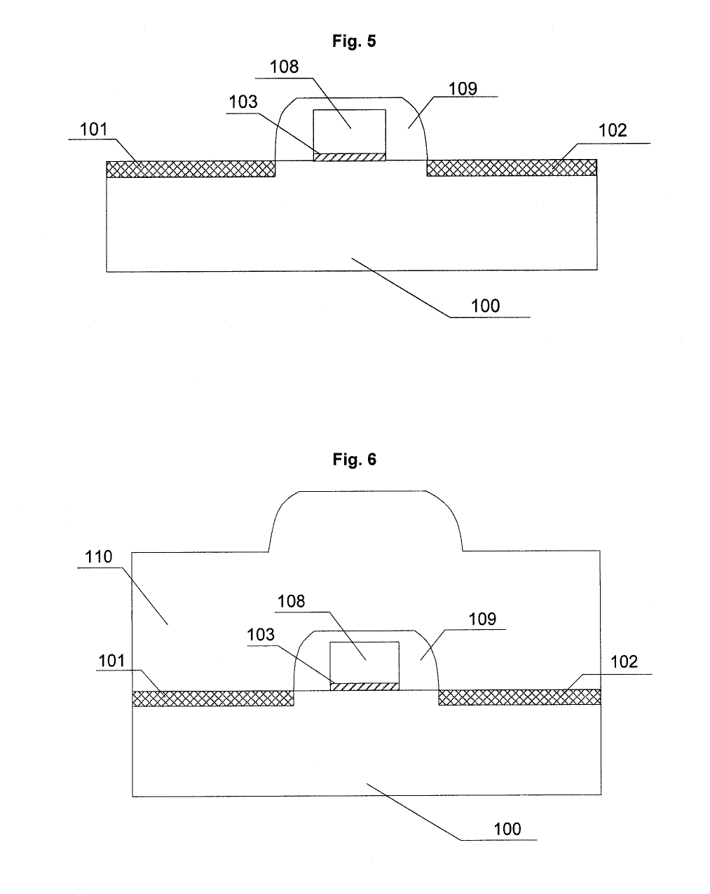

The method for manufacturing the transistor can be performed by means of well-known process. The embodiments of the present invention are shown in the schematic views of FIGS. 5-12.

An exemplary method for manufacturing the transistor structure according to the present invention may include the following steps:

In step 1, a source, a drain, a gate high-K dielectric layer, a sacrificial gate (generally, a polysilicon gate) and a masking layer are produced on a silicon wafer. As shown in FIG. 5, a semiconductor device has a substrate 100, a source 101, a drain 102, a gate high-K dielectric layer 103, a sacrificial gate 108 (generally, a polysilicon gate, or a gate formed from any other suitable materials);

and a masking layer 109. The gate high-K dielectric layer 103 is formed on a top surface of the substrate by a method known to a person skilled in the art. The gate high-K dielectric layer 103 includes a material with a dielectric constant larger than 4. The polysilicon gate 108 is formed on the gate high-K dielectric layer 103, for example, by chemical vapor deposition of polysilicon. The masking layer 109 is formed around the polysilicon gate 108 by suitable deposition and selective etching. The masking layer 109 includes a material such as silicon oxide, silicon nitride, or a mixture thereof. The source 101 and the drain 102 are formed by ion implantation.

In step 2, the interlayer dielectric is deposited. As shown in FIG. 6, the interlayer dielectric (ILD) 110 is formed on the source 101, the drain 102, and the masking layer 109. The interlayer dielectric 110 can be silicon oxide, such as SiO₂, boro-phospho-silicate-glass (BPSG), boro-silica glass (BSG), phospho-silicate glass (PSG), and undoped silicate glass (USG).

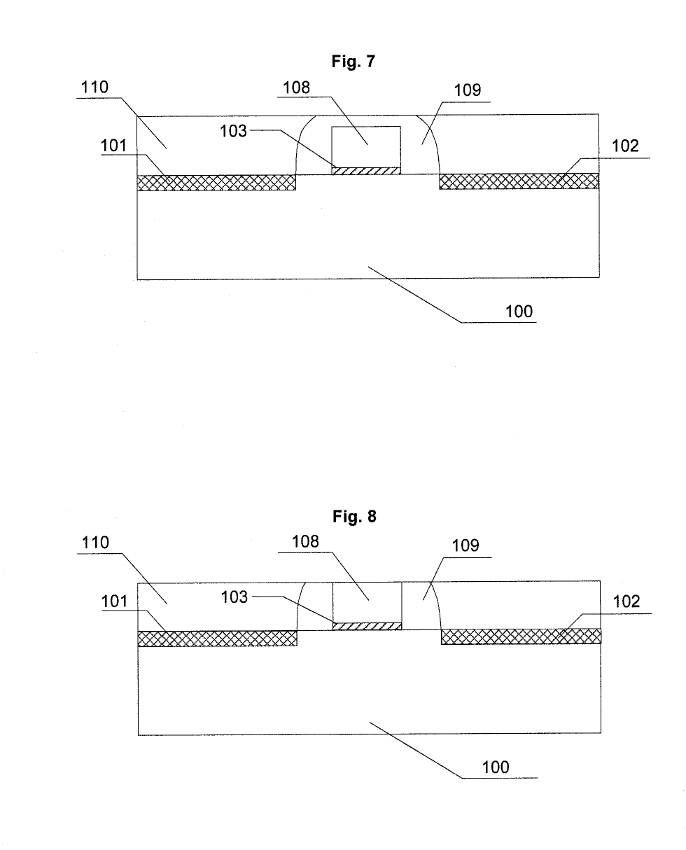

In step 3, the interlayer dielectric is processed. As shown in FIG. 7, the interlayer dielectric (ILD) 110 is partly removed by chemical mechanical planarization (CMP) to expose the masking layer 109.

In step 4, the masking layer is removed. As shown in FIG. 8, the top of the masking layer 109 is partly removed by mechanical planarization (CMP) or reactive ion etching (RIE), to expose the polysilicon gate 108.

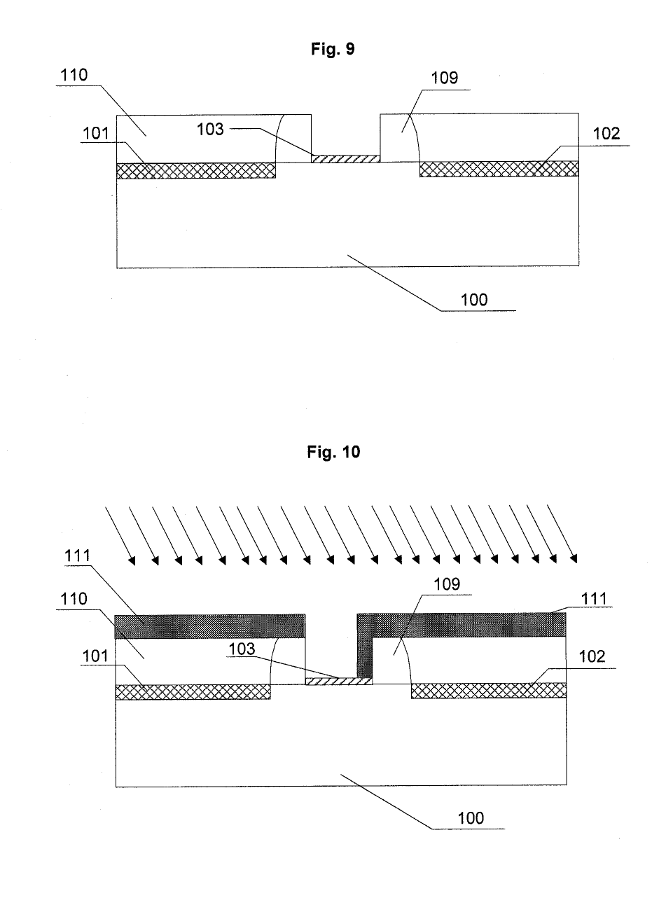

In step 5, the polysilicon gate 108 is etched to be removed. As shown in FIG. 9, the polysilicon gate 108 is removed and a cavity is formed on the gate high-K dielectric layer 103.

In step 5′, optionally, a metal film 103′ is formed on the gate high-K dielectric layer 103, to adjust the threshold voltage of the transistor. The metal film 103′ can be formed from pure metal Ti, Ta, Al, and/or nitride thereof, such as AlN, TaAlN, etc.

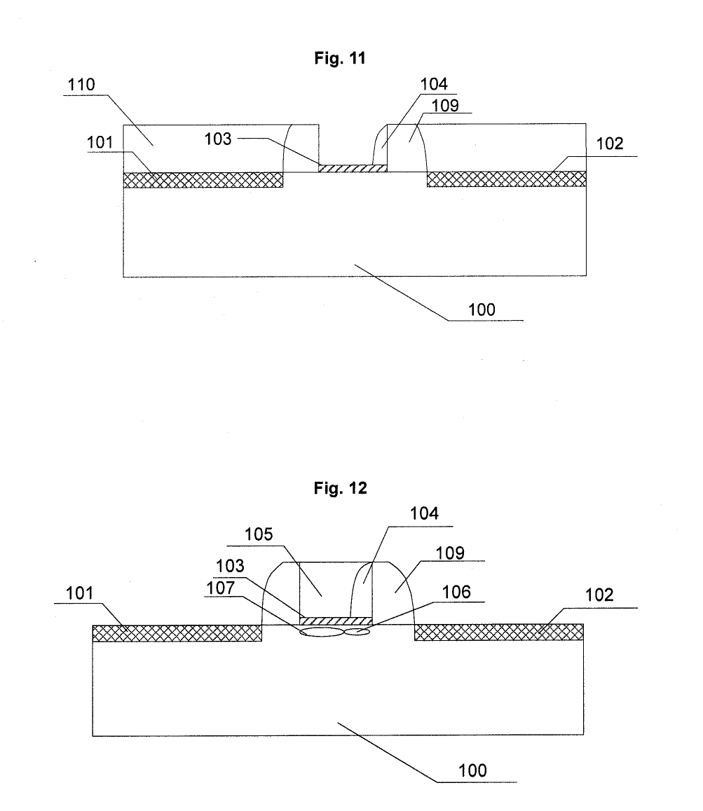

In step 6, the first oxygen absorbing layer is formed. As shown in FIG. 10, a first oxygen absorbing material 111 is slantingly deposited on the interlayer dielectric (ILD) 110 and the masking layer 109, to cover the gate high-K dielectric layer 103 at the drain side of the cavity. The first oxygen absorbing material can be pure metal Ti, Hf, Ta, W, and/or nitride thereof, etc. (cf. US Patent Application Publication No. 2009/0152651). The material will absorb oxygen and thereby reduce the thickness of the underlying interfacial layer. As shown in FIG. 11, the first oxygen absorbing layer 104 is formed on the gate high-K dielectric layer 104 in the cavity at the drain side by anisotropic etching.

In step 7, the second oxygen absorbing layer is formed. A second oxygen absorbing material is deposited in the other portion of the cavity. Then the second oxygen absorbing layer 105 is formed on the gate high-K dielectric layer 103 in the cavity at the drain side by chemical mechanical planarization (CMP). The second oxygen material can be the same as the first oxygen material.

The first oxygen absorbing layer 104 and the second oxygen absorbing layer 105 absorb oxygen and thereby reduce the equivalent oxide thickness (EOT) of the underlying interfacial layer. The first oxygen absorbing layer 104 has a stronger ability of absorbing oxygen than the second oxygen absorbing layer 105. Then the interfacial layer is formed, which includes a portion 106 and a portion 107 having different equivalent oxide thicknesses. The portion 107 is thicker than the portion 106. As a result, the portion 106 of the interfacial layer advantageously suppresses the short channel effect at the drain side, and the portion 107 of the interfacial layer prevents decrease of the carrier mobility at the source side.

Further, the asymmetric gate can implement different effective work functions by using different materials.

The present invention has been illustrated in details according to preferred embodiments. However, those skilled in the art can modify the present invention in forms or details without departing from the spirit and scope of the present invention. Therefore, the protection scope of the present invention is defined by the claims.

What is claimed is:

1. A transistor comprising:
a substrate having a channel region;
a source region and a drain region on two ends of the channel region of the substrate respectively;
a gate high-K dielectric layer between the source region and the drain region and on a top surface of the substrate above the channel region;
an interfacial layer under the gate high-K dielectric layer,
wherein the interfacial layer includes a first portion near the source region and a second portion near the drain region, wherein an equivalent oxide thickness of the first portion is larger than that of the second portion.

2. The transistor according to claim 1, wherein the equivalent oxide thickness of the first portion of the interfacial layer is larger than 0.5 nm, and the equivalent oxide thickness of the second portion of the interfacial layer is smaller than 0.5 nm.

3. The transistor according to claim 1, wherein the length of the first portion of the interfacial layer is less than ⅔ of the total length of the interfacial layer, and the second portion has a length equal to the remaining portion of the total length.

4. The transistor according to claim 1, wherein the transistor further comprises:
an oxygen absorbing layer on the top of the gate high-K dielectric layer.

5. The transistor according to claim 4, wherein the oxygen absorbing layer comprises:
a first oxygen absorbing layer at the drain region side; and
a second oxygen absorbing layer at the source region side,
wherein the first oxygen absorbing layer has a better oxygen absorbing ability than that of the second oxygen absorbing layer.

6. The transistor according to claim 5, wherein the first oxygen absorbing layer is formed from Ti, Hf, Ta, W, and/or nitride thereof.

7. The transistor according to claim 4, wherein a metal layer is further provided between the gate high-K dielectric layer and the oxygen absorbing layer.

8. A manufacturing method of a transistor comprising:
manufacturing a source, a drain, a gate high-K dielectric layer, a sacrificial gate, and a masking layer covering the sacrificial gate on a silicon wafer;
depositing an interlayer dielectric on the masking layer, the source, and the drain;
planarizing to remove the top of the interlayer dielectric to expose the top of the masking layer;
etching to remove the top of the masking layer to expose the top of the sacrificial gate;
etching to remove the sacrificial gate on the gate high-K dielectric layer to form a cavity;
forming a first oxygen absorbing layer in the cavity from a first oxygen absorbing material; and
forming a second oxygen absorbing layer in the remaining portions of the cavity from a second oxygen absorbing material,
wherein the first oxygen absorbing layer has a better oxygen absorbing ability than that of the second oxygen absorbing layer.

9. The method according to claim 8, wherein the first oxygen absorbing material is slantingly deposited to form the first oxygen absorbing layer at one time.

10. The method according to claim 8, wherein the first oxygen absorbing layer is formed from Ti, Hf, Ta, W, and/or nitride thereof.

11. The method according to claim 9, wherein the second oxygen absorbing material is deposited in the remaining portion of the cavity, and the second oxygen absorbing layer is formed on the gate high-K dielectric layer at the source side in the cavity by chemical mechanical planarization.
